(19) United States
(12) Patent Application Publication
(10) Pub. No.: US 2011/0156200 A1
(43) Pub. Date: Jun. 30, 2011

(54) SEMICONDUCTOR DEVICE

(75) Inventor: Yasuhiro Shimura, Kanagawa-ken (JP)

(73) Assignee: Kabushiki Kaisha Toshiba, Tokyo (JP)

(21) Appl. No.: 12/979,648

(22) Filed: Dec. 28, 2010

(30) Foreign Application Priority Data
Dec. 28, 2009 (JP) P2009-298509

(51) Int. Cl. H01L 23/58

(52) U.S. Cl. 257/506; 257/E23.002

(57) ABSTRACT

A semiconductor memory device includes a semiconductor substrate provided with active areas and an element-isolating insulating film isolating the active areas from each other, the active areas each extending in a first direction; an interlayer insulating film formed on a surface of the semiconductor substrate; and a contact member provided in the interlayer insulating film, and including a first portion and a second portion, the first portion electrically connected to a wire above the semiconductor substrate, the second portion having a shape that spreads out of the first portion as viewed from above and connected to the first portion. A maximum width of the second portion measured in the first direction is larger than a width of the first portion measured in the first direction, and the second portion is in contact with the interlayer insulating film that surrounds the first portion.

### CROSS-REFERENCE TO RELATED APPLICATIONS

This application is based upon and claims the benefit of priority from Japanese Patent Application No. 2009-298509, filed Dec. 28, 2009, the entire contents of which are incorporated herein by reference.

### BACKGROUND OF THE INVENTION

### Field of the Invention

Embodiments described herein relate generally to a semiconductor device including a contact member connected to an active area.

### BACKGROUND

In recent years, as semiconductor devices have become more highly integrated with higher density, the contact area between the semiconductor substrate and each contact member has become smaller and smaller.

A smaller contact area between the semiconductor substrate and each contact member, however, increases the contact resistance between the semiconductor substrate and the contact member, and thus may cause malfunction of a semiconductor element formed on the semiconductor substrate and electrically connected to the contact member.

One conventional method to reduce the contact resistance between a convex semiconductor layer and a contact portion is to provide a convex semiconductor layer formed on the semiconductor substrate; and a contact portion which is in contact with the top surface of the convex semiconductor layer and a portion of the sidewall thereof and is thus electrically connected to the convex semiconductor layer (see, for example, JP-A 2007-123415).

However, such reduction in the contact resistance conventionally achieved is now more likely to become insufficient.

In addition, also from the viewpoint of saving power consumption of semiconductor devices of recent years, further reduction in the contact resistance between the semiconductor substrate and each contact member is demanded.

### BRIEF DESCRIPTION OF THE DRAWINGS

FIG. 1 is a plan view showing the configuration of a semiconductor device according to a first embodiment.

FIG. 2 is a perspective view showing an exemplary connection state between a semiconductor substrate and a contact member of the semiconductor device according to the first embodiment.

FIG. 3A is a sectional view taken along the line A-A of FIG. 1.

FIG. 3B is a sectional view taken along the line B-B of FIG. 1.

FIGS. 4A to 4D are diagrams showing a flow of manufacturing processes of the semiconductor device according to the first embodiment and viewed in a first direction.

FIGS. 5A to 5D are diagrams showing a flow of manufacturing processes of the semiconductor device according to the first embodiment and viewed in a second direction.

FIG. 6A is a sectional view showing the connection state between the contact member and the semiconductor substrate of the semiconductor device according to the first embodiment.

FIG. 6B is a sectional view showing the connection state between a contact portion and a convex semiconductor layer of a conventional semiconductor device.

FIG. 7 is a perspective view showing an exemplary connection state between a semiconductor substrate and a contact member of a semiconductor device according to a modified example of the first embodiment.

FIG. 8A is a sectional view taken along the line A-A of FIG. 1.

FIG. 8B is a sectional view taken along the line B-B of FIG. 1.

FIG. 9 is a perspective view showing an exemplary connection state between a semiconductor substrate and a contact member of a semiconductor device according to a second embodiment.

FIG. 10A is a sectional view taken along the line A-A of FIG. 1.

FIG. 10B is a sectional view taken along the line B-B of FIG. 1.

### DETAILED DESCRIPTION OF THE PREFERRED EMBODIMENTS

In general, according to one embodiment, a semiconductor device includes: a semiconductor substrate provided with active areas and an element-isolating insulating film isolating the active areas from each other, the active areas each extending in a first direction; an interlayer insulating film formed on a surface of the semiconductor substrate; and a contact member provided in the interlayer insulating film, and including a first portion and a second portion, the first portion electrically connected to a wire above the semiconductor substrate, the second portion having a shape that spreads out of the first portion as viewed from above and connected to the first portion, wherein a maximum width of the second portion measured in the first direction is larger than a width of the first portion measured in the first direction, and the second portion is in contact with the interlayer insulating film that surrounds the first portion.

Some embodiments are described below by referring to the drawings. In the course of the following description, each portion that appears in various drawings is denoted by the same reference numeral.

(First Embodiment)

[Configuration of First Embodiment]

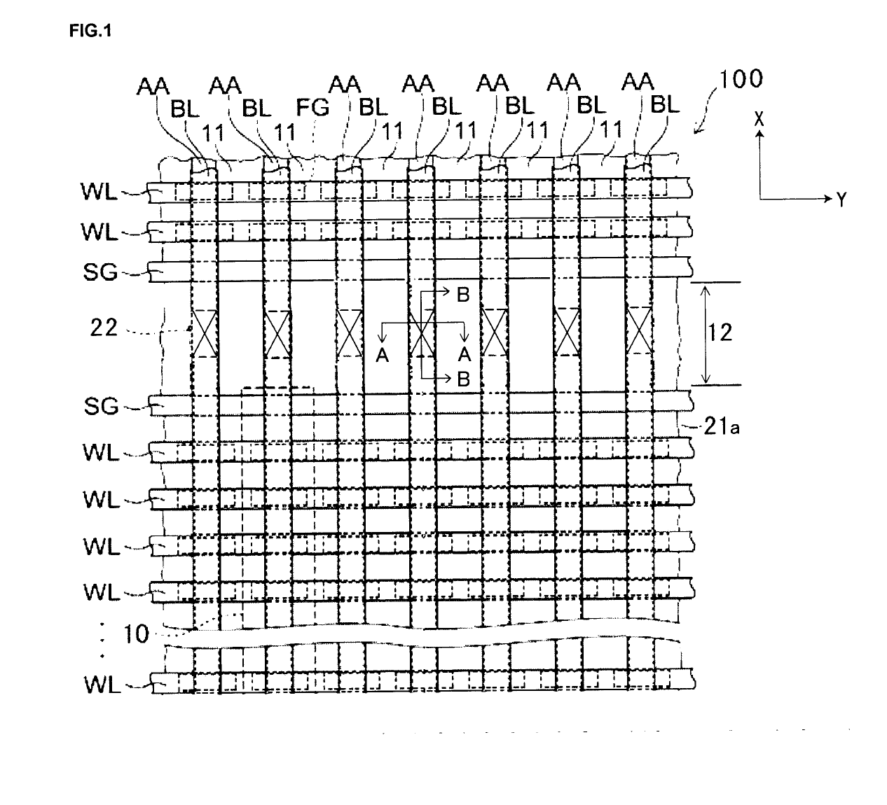

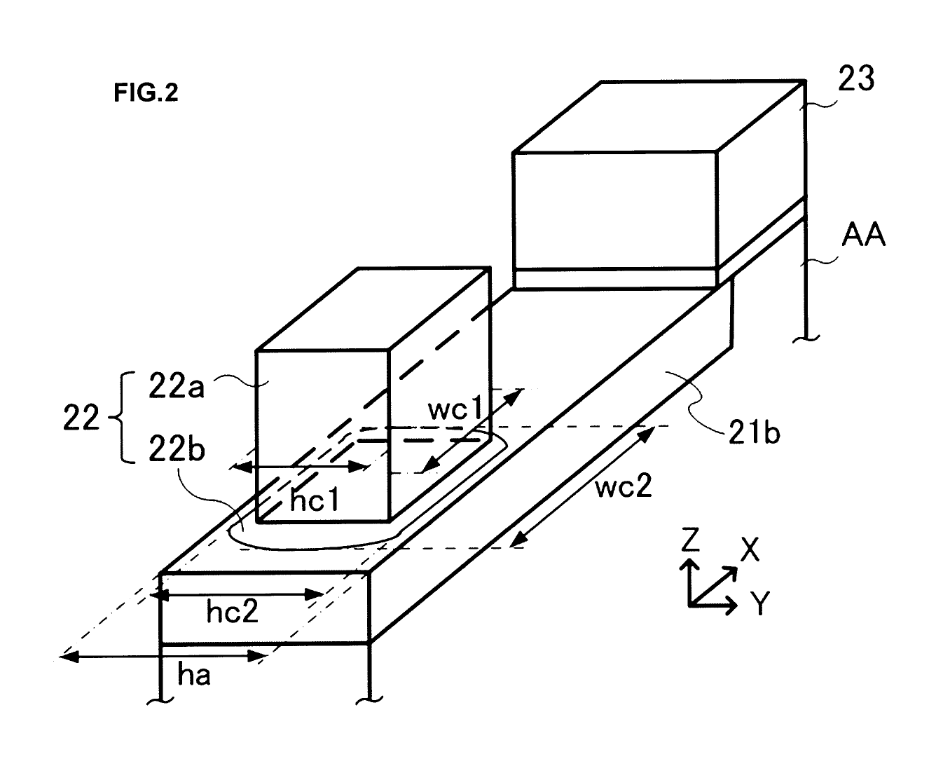

The configuration of a semiconductor device according to a first embodiment is described by referring to FIGS. 1 and 2. FIG. 1 is a plan view showing the configuration of the semiconductor device according to the first embodiment. FIG. 2 is a perspective view showing an exemplary connection state between a semiconductor substrate and a contact member of the semiconductor device according to the first embodiment.

As FIG. 1 shows, a NAND-type nonvolatile memory semiconductor device 100 as an example of this first embodiment includes a semiconductor substrate 21a, NAND strings 10, contact members 22 connected to the semiconductor substrate 21a, tungsten wires (not illustrated) formed on the contact members 22, metal wires BL, and plugs (not illustrated) formed on the tungsten wires and connecting the tungsten wires to the metal wires BL.

<<Semiconductor Substrate>>

As FIG. 1 shows, a plurality of active areas AA, each extending in a first direction (in the X-direction in FIG. 1), are formed in the surface portion of the semiconductor substrate 21a. Element-isolating insulating films 11 (for example, STI structures) are formed so as to isolate the active areas AA from each other. The bit lines BL are provided respectively over the active areas AA to overlap the corresponding active areas AA. A plurality of word lines WL each extending in a direction (i.e., in the Y-direction) orthogonal to the first direction in FIG. 1 are arranged at predetermined intervals in the X-direction. Selection gate lines SG are formed so as to sandwich the plurality of word lines WL.

<<NAND String>>

Each memory cell is a MOS-type memory cell. As FIG. 1 shows, each of the plurality of memory cells is formed at the intersection of a word line WL and an active area AA as viewed from above.

In addition, each NAND string 10 includes: a plurality of memory cells that are connected in series in the longitudinal direction of the corresponding active area AA (in the X-direction in FIG. 1); and two selection gate transistors that are provided respectively on the two end portions of the plurality of memory cells. The plurality of NAND strings 10 are formed in a matrix shape.

<<Contact Member>>

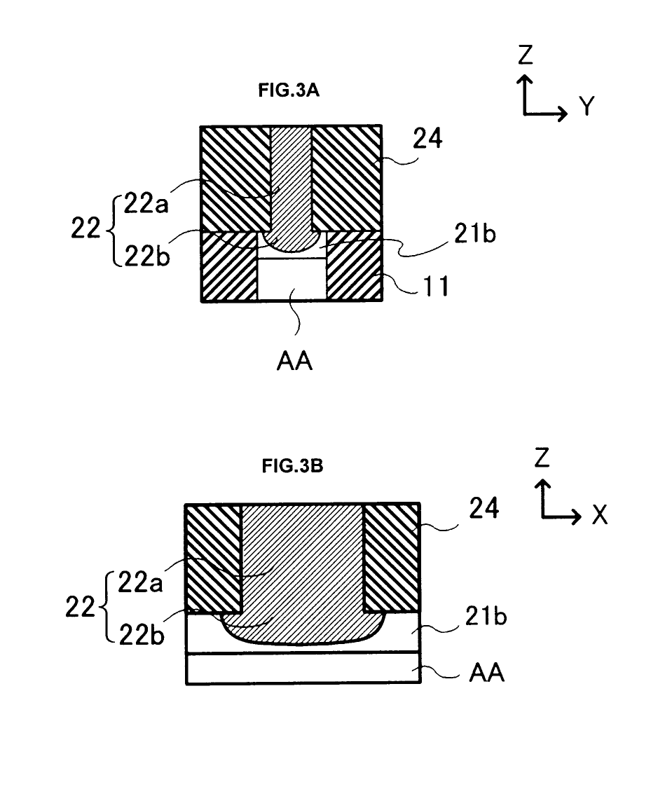

Each contact member 22 is connected to both the corresponding tungsten wire (not illustrated) that is formed as a layer on the contact member 22, and an N type diffusion layer 21b that is formed in the corresponding active area AA within the semiconductor substrate 21a. Each contact member 22 is provided in a portion located between two NAND strings 10 that are adjacent to each other in the longitudinal direction of the corresponding active area AA. Now, an exemplary connection state between the contact member 22 and the N type diffusion layer 21b is described by referring to FIGS. 2 to 3B. FIG. 3A is a sectional view taken along the line A-A of FIG. 1. FIG. 3B is a sectional view taken along the line B-B of FIG. 1.

As FIGS. 3A and 3B show, each contact member 22 is formed in the corresponding N type diffusion layer 21b and in an interlayer insulating film 24 formed on the corresponding element-isolating insulating film 11. A portion of the contact member 22 is buried in the N type diffusion layer 21b located within the corresponding active area AA. As FIGS. 2 to 3B show, each contact member 22 includes a first contact member 22a (first portion) and a second contact member 22b (second portion), which are defined as follows. The portion surrounded by the interlayer insulating film 24 is defined as the first contact member 22a, whereas the portion surrounded by the N type diffusion layer 21b is defined as the second contact member 22b.

As FIG. 2 shows, the first contact member 22a has a substantially cuboid-shaped structure defined by a rectangular sectional shape together with a constant height. The rectangular section has a width hc1 in the second direction (Y-direction) and a width wc1 in the first direction (X-direction).

The width hc1 of the first contact member 22a measured in the second direction is shorter than the width ha of the active area AA measured in the second direction. The width wc1 is preferably constant.

What is described next is the top surface of the second contact member 22b (i.e., the surface of the second contact member 22b obtained by cutting the contact member 22 along the same plane as the top surface of the N type diffusion layer 21b). As FIG. 2 shows, the maximum width hc2 of the top surface measured in the second direction is longer than the width hc1 of the first contact member 22a, whereas the maximum width wc2 of the top surface measured in the first direction is longer than the width wc1 of the first contact member 22a. In addition, the top surface has arc-shaped or rounded corners. Specifically, if the bottom surface of the first contact member 22a (i.e., the surface of the first contact member 22a obtained by cutting the contact member 22 along the same plane as the top surface of the N type diffusion layer 21b) is connected to the top surface of the second contact member 22b, some portions of the top surface of the second contact member 22b are not covered by the first contact member 22a (i.e., some portions of the top surface of the second contact member 22b are located outside of the bottom surface of the first contact member 22a). Such portions are covered with the interlayer insulating film 24. In addition, the width hc2 of the second contact member 22b is shorter than the width ha of the active area AA.

As FIG. 3A shows, in a section of the second contact member 22b viewed in the first direction, the portion of the second contact member 22b in contact with the N type diffusion layer 21b has a substantially arc shape which is convex downwards (i.e., in the negative Z-direction in FIG. 2). Likewise, as FIG. 3B shows, in a section of the second contact member 22b viewed in the second direction, the portion of the second contact member 22b in contact with the N type diffusion layer 21b has a substantially arc shape which is convex downwards. The substantially arc-shaped structure is formed by an isotropic etching process, and may have a shape that is not an arc shape in a strict sense. In addition, the top surface of the second contact member 22b does not have to be flush with the top surface of the N type diffusion layer 21b. For example, the top surface of the second contact member 22b may have a shape of a sloping surface inclined upwards with respect to the top surface of the N type diffusion layer 21b. The top of the sloping surface is covered with the interlayer insulating film 24.

[Manufacturing Method of First Embodiment]

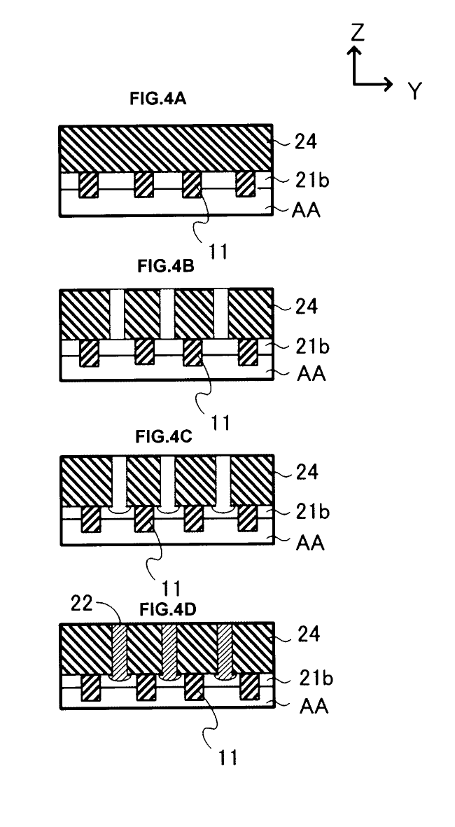

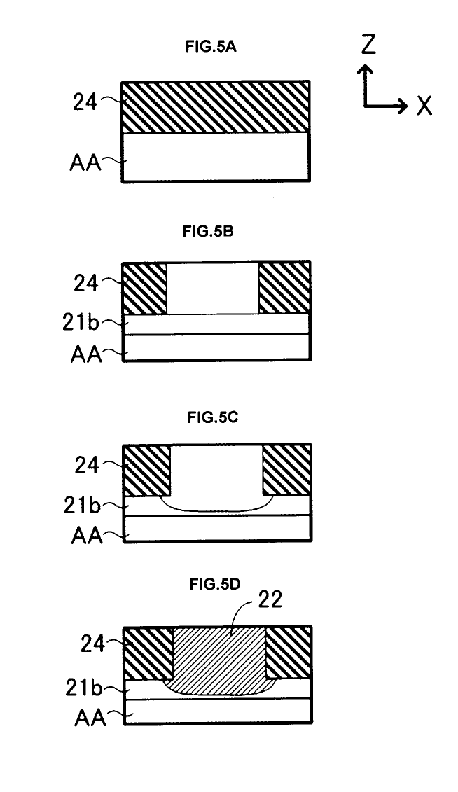

A method of manufacturing the semiconductor device of the first embodiment is described by referring to sectional views shown in FIGS. 4A to 5D showing manufacturing processes of the semiconductor device. The sectional views in FIGS. 4A to 4D are seen from the first direction whereas the ones in FIGS. 5A to 5D are seen from the second direction.

In the semiconductor substrate 21a, element isolating regions are formed with element-isolating insulating films 11. Then, ions are implanted into the regions where N channel regions and P channel regions are to be formed to form a well. Subsequently, the word lines WL and the selection gate lines SG are formed by depositing polysilicon and the like and then performing processing such as lithography and etching. Note that the deposition of the polysilicon and the like may precede the formation of the element isolating regions. Thereafter, the N type diffusion layers 21b are formed, by an ion-implantation method, in some regions of the surface of the semiconductor substrate 21a where the contact members 22 are to be formed.

After that, the interlayer insulating film 24 is formed on the element-isolating insulating films 11 and the N type diffusion layers 21b (see FIGS. 4A and 5A).

Then, a photoresist (not illustrated) is applied to the entire surface of the interlayer insulating film 24, and a desired resist pattern is formed by lithography. Subsequently, using the resist pattern as a mask, the interlayer insulating film 24 is dry-etched (e.g., by a RIE process) to form grooves (grooves for contacts) in the interlayer insulating film 24 (see FIGS. 4B and 5B). Each groove is formed to have a width hc1 in the second direction and a width wc1 in the second direction.

Thereafter, an isotropic etching process is performed on the N type diffusion layer 21b. The N type diffusion layers 21b exposed to the grooves for contacts are thus isotropically etched (see FIGS. 4C and 5C). For example, the isotropic etching process may be a wet etching process using an HNO₃ solution containing HF, or may be a dry etching process which uses a halide gas containing Cl₄ and which is capable of selectively etching only the N type diffusion layers 21b.

After that, the contact members 22 are formed by burying metal layers in the grooves for contacts (see FIGS. 4D and 5D). Note that a barrier metal layer may be formed between the metal layer and each of the N type diffusion layers 21b and the first insulating film 24.

Each of the contact members 22 thus manufactured has a structure where a portion of the contact member 22 is buried in the N type diffusion layer 21b. Accordingly, a semiconductor device thus provided is capable of further reducing the contact resistance between the semiconductor substrate 21a and each contact member 22.

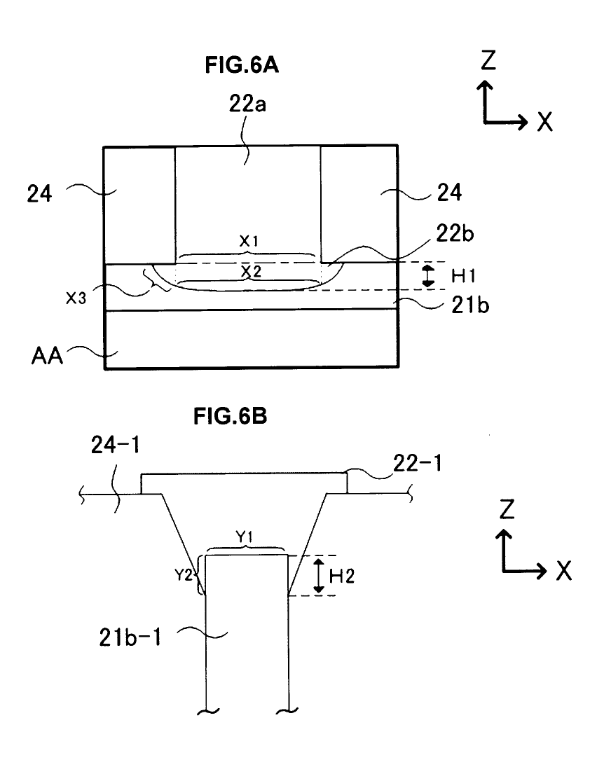

Hereinbelow, a description is given, by referring to FIGS. 6A and 6B, of a comparison between the contact area of each second contact member 22b with the corresponding N type diffusion layer 21b in the first embodiment and the contact area of each contact portion 22-1 with the corresponding convex semiconductor layer 21b-1 in JP-A 2007-123415. Each first contact member 22a is assumed to have a columnar shape. Note that if each first contact member 22a has a shape of a circular column, the width wc1 (=hc1) and the wc2 (=hc2) are equal to the diameter of their respective circles.

FIG. 6A is a sectional view showing the connection state between each contact member and the semiconductor substrate in the semiconductor device of the first embodiment. FIG. 6B is a sectional view showing the connection state between each contact portion and the convex semiconductor layer of the conventional semiconductor device. For the sake of simpler description, hatching is omitted from the drawings of FIGS. 6A and 6B.

Note that the height H1 in FIG. 6A is assumed to be equal to the height H2 in FIG. 6B. In addition, the area of a top-surface region Y1, shown in FIG. 6B, of the semiconductor layer 21b-1 is assumed to be equal to the area of a contact region X1, in this first embodiment, that is, the bottom surface of each first contact plug 22a.

As FIG. 6A shows, the contact surface between the second contact member 22b and the N type diffusion layer 21b is subdivided into a region X2 and a region X3 defined as follows. The region X2 is a region of the contact surface formed by projecting an image of the first contact member 22a onto the contact surface between the second contact member 22b and the N type diffusion layer 21b. The region X3 is the remaining region of the contact surface between the second contact member 22b and the N type diffusion layer 21b. In addition, as FIG. 6B shows, a region Y2 is defined as the contact surface between the contact portion 22-1 and a sidewall of the semiconductor layer 21b-1.

As FIG. 6A shows, the connection portion between the second contact member 22b and the N type diffusion layer 21b in this first embodiment has a substantially arc shape which is convex downwards. Accordingly, the region X2 is larger than the region Y1, and the region X3 is larger than the region Y2. Consequently, the contact area between each second contact member 22b and the corresponding N type diffusion layer 21b of this first embodiment is larger than the contact area between each contact portion 22-1 and the corresponding protruding semiconductor layer 21b-1 of JP-A 2007-123415.

As a result, the contact resistance between each second contact member 22b and the corresponding N type diffusion layer 21b of the semiconductor substrate 21a in this first embodiment can be reduced.

Hence, the current flows between each contact member 22 and the corresponding N type diffusion layer 21b can be prevented from decreasing. To put it differently, the current that flows through each NAND string 10 can be prevented from decreasing. As a result, the reading speed of the NAND-type flash memory can be increased and malfunctions of the element can be decreased.

In addition, in this first embodiment, the surfaces of the N type diffusion layer 21b are isotropically etched. For this reason, the defects formed during the well formation or the ion implantation for forming the N type diffusion layers 21b can be removed simultaneously by the etching. Accordingly, the contact resistance between each contact member 22 and the semiconductor substrate 21a can be further reduced. Moreover, since the defects in the layers are removed, the variation of the values of the contact resistance can be reduced. As a consequence, malfunction of the semiconductor element can be further reduced.

In addition, the isotropic etching process performed on the surfaces of the N type diffusion layers 21b can remove simultaneously the natural oxide films formed, in the process shown in FIGS. 4B and 5B, on the surfaces of the semiconductor substrate 21a exposed in the grooves for contacts. Accordingly, the contact resistance between each contact member 22 and the corresponding N type diffusion layer 21b can be further reduced.

(Modified Example of First Embodiment)

In the above-described first embodiment, the width hc2 of each second contact member 22b measured in the second direction is shorter than the width ha of each active area AA measured in the second direction, and the entirety of each first contact member 22a is formed over the active area AA. However, misalignment may occur when the above-described lithography technique is performed. If such misalignment occurs, a portion of each first contact member 22a may spread out of the active area AA and may thus be formed over the adjacent element isolating region.

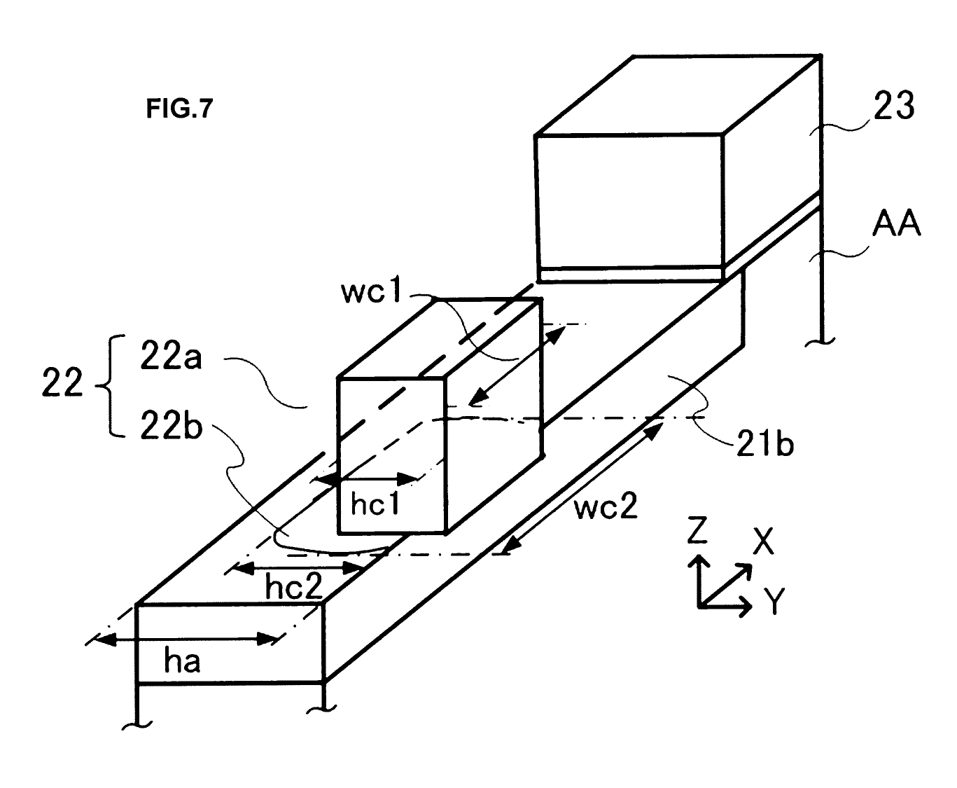

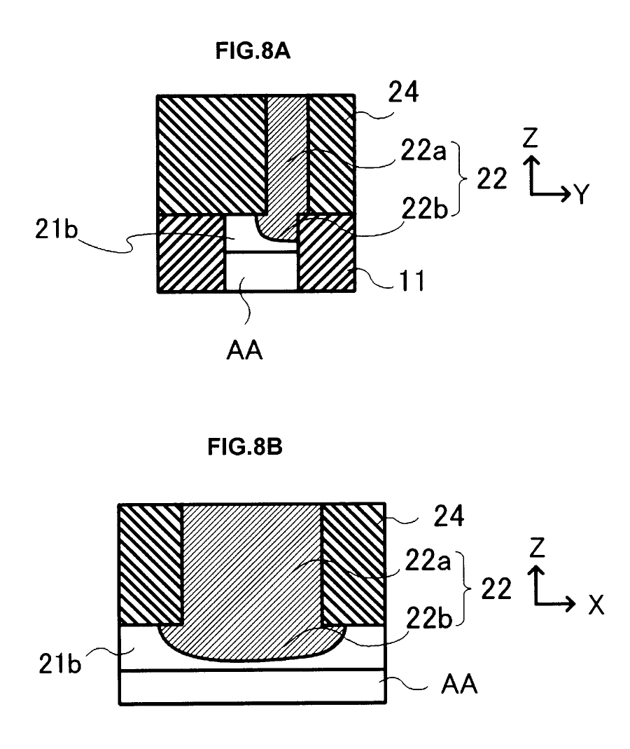

The configuration of a semiconductor device according to a modified example of the first embodiment is described below by referring to FIGS. 7 to 8B.

The semiconductor device of the modified example of the first embodiment differs from the semiconductor device of the first embodiment in the position and the shape of each contact member 22, but the other constituent parts are identical to their respective counterparts of the semiconductor device of the first embodiment. Accordingly, the constituent parts other than the principal constituent parts of the semiconductor device are omitted from FIGS. 7 to 8B.

FIG. 7 is a perspective view showing an exemplary contact state between each contact member and the semiconductor substrate in the semiconductor device according to the modified example of the first embodiment. FIG. 8A is a sectional view taken along the line A-A of FIG. 1. FIG. 8B is a sectional view taken along the line B-B of FIG. 1. In addition, the manufacturing method of the semiconductor device according to the modified example of the first embodiment is the same as that of the first embodiment.

[Configuration of Modified Example of First Embodiment]

Detailed description of the constituent parts identical to those in the first embodiment is also omitted from the following description. Only the different constituent parts (i.e., contact members 22) are described.

<<Contact Member>>

As in the case of the first embodiment, each contact member 22 is defined by being subdivided into a first contact member 22a and a second contact member 22b. The relationship between the width hc1 of the first contact member 22a and the width ha of the active area AA as well as the relationship between the width wc1 of the first contact member 22a and the width wc2 of the second contact member 22b are the same as those in the first embodiment.

The first contact member 22a has a substantially cuboid-shaped structure defined by a rectangular sectional shape together with a constant height. The rectangular section has a width hc1 in the second direction and a width wc1 in the first direction. Misalignment that occurs in a photolithography technique causes a portion of the first contact member 22a to shift from the corresponding active area AA in the second direction. For example, a portion of the first contact member 22a shifts from the corresponding active area AA in the positive Y-direction in FIG. 8A. As FIG. 8A shows, the bottom surface of the first contact member 22a is in contact with both the element-isolating insulating film 11 and the second contact member 22b.

The second contact member 22b has a shape formed by etching isotropically and removing a portion of the N type diffusion layer 21b in the surface of the semiconductor substrate 21a exposed when grooves for contacts are formed in the interlayer insulating film 24. For example, in the case shown in FIG. 8A, the connection portion between the second contact member 22b and the N type diffusion layer 21b has a substantially arc shape which is convex downwards (in the negative Z-direction in FIG. 2). To be more specific, a portion, on a side in the second direction, of the bottom surface of the first contact member 22a is in contact with the top surface of the element-isolating insulating film 11. Moreover, a sidewall of the second contact member 22b is in contact with a sidewall of the element-isolating insulating film 11.

Consequently, each of the contact members 22 has a structure where a portion of the contact member 22 is buried in the corresponding N type diffusion layer 21b. Accordingly, a semiconductor device thus provided is capable of further reducing the contact resistance between each second contact member 22b and the corresponding N type diffusion layer 21b of the semiconductor substrate 21a.

Now, suppose a case where the direction and the distance of the misalignment of the contact member 22b with respect to the N type diffusion layer 21b in this embodiment are equal to the direction and the distance of the misalignment of the contact portion with respect to the convex semiconductor layer in JP-A 2007-123415. In this case, a similar effect to the one obtainable in the first embodiment can be obtained. Specifically, the contact area between each contact member 22b and the corresponding N type diffusion layer 21b in this embodiment is larger than the contact area between each contact portion and the corresponding semiconductor layer in a case where the contact portion is misaligned to the semiconductor layer in JP-A 2007-123415. This is because the contact portion between each contact member 22b and the corresponding N type diffusion layer 21b has a substantially arc-shaped section which is convex downwards in this embodiment. Accordingly, the contact resistance between each contact member 22 and the semiconductor substrate 21a can be reduced.

(Second Embodiment)

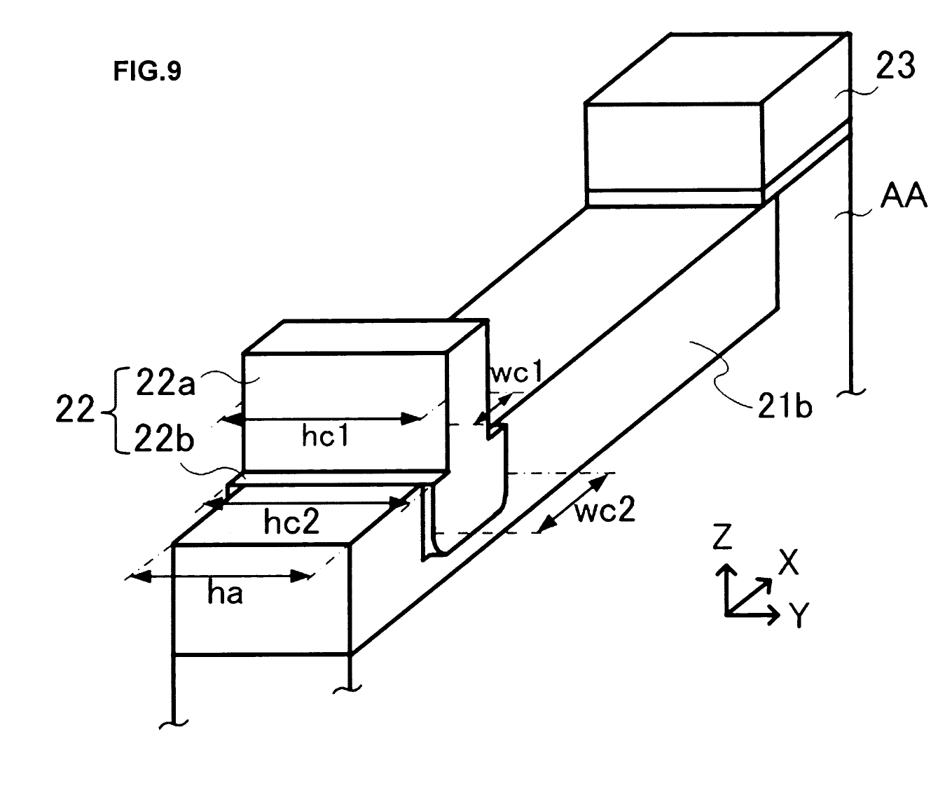

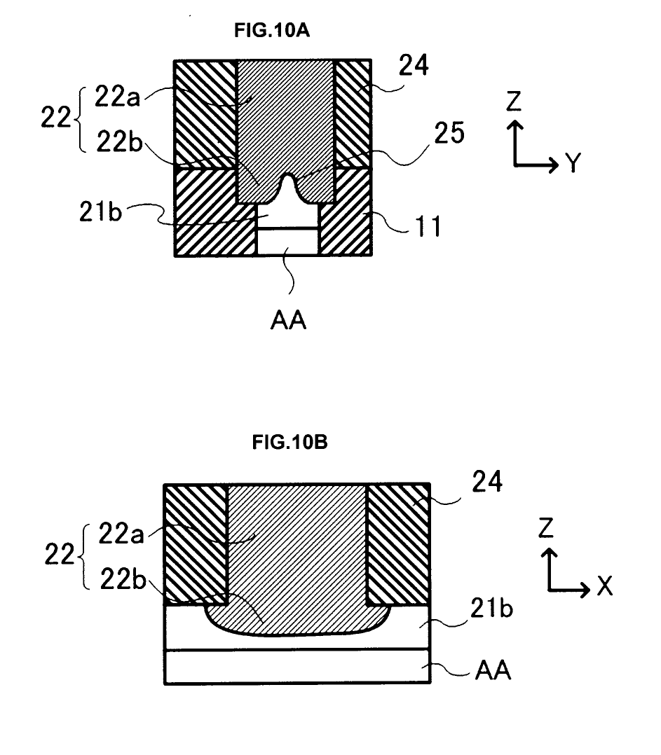

A semiconductor device according to a second embodiment is described by referring to FIGS. 9 to 10B. FIG. 9 is a perspective view showing an exemplary connection state between each contact member and a semiconductor substrate in the semiconductor device according to the second embodiment. FIG. 10A is a sectional view taken along the line A-A of FIG. 1. FIG. 10B is a sectional view taken along the line B-B of FIG. 1.

The semiconductor device of the second embodiment differs from the semiconductor device of the first embodiment in that each of the widths hc1 and hc2 of each contact member 22 measured in the second direction is longer than the width ha of each active area AA. The other constituent parts of the semiconductor device of the second embodiment are identical to their respective counterparts of the first embodiment. Note that there may be a case where the variations caused by the lithography process make the width of a contact member 22 measured in the second direction longer than the width of each active area AA. The constituent parts of the semiconductor device other than the principal constituent parts are omitted from FIGS. 9 to 10B. In addition, the manufacturing method of the semiconductor device of this second embodiment is identical to that of the first embodiment.

[Configuration of Second Embodiment]

Detailed description of the identical constituent parts to those in the first embodiment is omitted also from the following description. Only the different constituent parts (i.e., N type diffusion layers 21b and contact members 22) are described.

<<Semiconductor Substrate>>

As FIG. 10A shows, the N type diffusion layer 21b that is in contact with the contact member 22 has a shape including a protruding portion 25 that substantially protrudes upwards (in the positive Z-direction). The protruding portion 25 is located in the central portion of the width, in the second direction, of the active area AA.

The protruding portion 25 is formed in the following way. Firstly, grooves for contacts are formed both in element-isolating insulating films 11 and an interlayer insulating film 24 in a way to expose the top surface and sidewall of the N type diffusion layer 21b. Then, an isotropic etching process is performed on the N type diffusion layer 21b.

<<Contact Member>>

As in the case of the first embodiment, each contact member 22 is defined by being subdivided into a first contact member 22a and a second contact member 22b. As FIG. 9 shows, the width hc1 of the first contact member 22a, the width hc2 of the second contact member 22b, and the width ha of the active area AA are set to satisfy the following Formula 1.

hc1=hc2>ha (Formula 1)

As FIG. 10A shows, if the sections of the second contact member 22b and of the N type diffusion layer 21b are viewed in the first direction, the top surface of the N type diffusion layer 21b is in contact with the second contact member 22b alone, and is not in contact with the interlayer insulating film 24.

Contact members 22 are formed respectively in the grooves for contacts formed both in the element-isolating insulating films 11 and in the interlayer insulating film 24. Accordingly, each second contact member 22b is formed in a way to be engaged with the protruding portion 25 of the corresponding N type diffusion layer 21b. The shape of each protruding portion 25 can be changed by adjusting the conditions for the isotropic etching process so as to increase the contact area between the N type diffusion layer 21b and the second contact member 22b.

As FIG. 9 shows, as in the case of the first embodiment, the maximum width wc2 of the second contact member 22b measured in the first direction is longer than the width wc1 of the first contact member 22a measured in the first direction. As FIG. 10B shows, if a section of the second contact member 22b is viewed from the second direction, the connection portion between the N type diffusion layer 21b and the second contact member 22b has a substantially arc shape which is convex downwards.

Consequently, each of the contact members 22 has a structure where a portion of the contact member 22 is buried in the corresponding N type diffusion layer 21b. Accordingly, a semiconductor device thus provided is capable of further reducing the contact resistance between each second contact member 22b and the corresponding N type diffusion layer 21b of the semiconductor substrate 21a.

In this second embodiment, the protruding portion 25 formed in each N type diffusion layer 21b is located in the central position of the width, measured in the second direction, of the corresponding active area AA. Accordingly, even if the misalignment in the photolithography technique shifts the position of each contact member 22 from the corresponding active area AA in the second direction, each contact member 22 is more likely to be formed on the corresponding protruding portion 25. Accordingly, the contact area between each second contact member 22b and the corresponding N type diffusion layer 21b can be increased further than in the case of JP-A 2007-123415.

In addition, in this second embodiment, each of the widths hc1 and hc2 of each contact member 22 measured in the second direction can be made larger than the width ha of each active area AA measured in the second direction. Accordingly, the contact resistance between each second contact member 22b and the corresponding N type diffusion layer 21b can be reduced further than that in the case of the first embodiment.

The invention of this application is not limited to the above-described embodiments. Rather, in the stages of actually carrying out the invention, various modifications can be made without departing from the gist of the invention. For example, in the embodiments, each contact member 22 may be provided as a polysilicon plug. Accordingly, providing the contact members with a barrier metal layer is no longer necessary. As a consequence, the contact resistance between each second contact member 22b and the corresponding N type diffusion layer 21b of the semiconductor substrate 21a can be further reduced.

In addition, if, for example, N type polysilicon plugs doped with phosphorus are used, phosphorus diffusion from each N type polysilicon plug to the corresponding N type diffusion layer 21b occurs in the interface between the N type polysilicon plug and the N type diffusion layer 21b of the semiconductor substrate 21a. As a consequence, a higher density of electron carriers is achieved at the interface between each contact member 22b and the corresponding N type diffusion layer 21b in the semiconductor substrate 21a, and the contact resistance and the variation of the contact resistance can be further reduced.

In addition, in the second embodiment, the widths hc1, hc2, and ha are defined to satisfy the relationship of Formula 1. Alternatively, the widths hc1, hc2, and ha may be set to satisfy the following Formula 2.

hc1=hc2=ha (Formula 2)

Also in this case, the contact resistance between each second contact member 22b and the corresponding N type diffusion layer 21b in the semiconductor substrate 21a can be reduced as in the cases of the first and the second embodiments.

In addition, each contact member 22 does not have to have a substantially cuboid shape with a rectangular cross section. Alternatively, each contact member may have a substantially circular-column shape with an ellipsoidal cross section. Note that if each contact member 22 has a circular columnar shape, the above-mentioned widths are defined as follows. Each of the widths wc1 and wc2 is the width in the longitudinal direction (major axis) of the ellipsoid, whereas each of the widths hc1 and hc2 is the maximum width in the shorter direction (minor axis) of the ellipsoid.

In addition, the embodiments include various aspects of the invention at different stages. Various aspects of the invention can be extracted by combining appropriately the disclosed plural constituent elements. For example, even if some of the constituent elements that are described in the embodiments are removed, the configuration without such removed constituent elements can be extracted as an aspect of the invention as long as the objects described in the summary can be achieved and the effects described in the corresponding section of this specification can be obtained.

1. A semiconductor device comprising:
a semiconductor substrate provided with active areas and an element-isolating insulating film isolating the active areas from each other, the active areas each extending in a first direction;
an interlayer insulating film formed on a surface of the semiconductor substrate; and
a contact member provided in the interlayer insulating film, and including a first portion and a second portion, the first portion electrically connected to a wire above the semiconductor substrate, the second portion being in contact with the substrate, having a downwardly convex shape, and being connected to the first portion,
wherein a maximum width of the second portion measured in the first direction is larger than a width of the first portion measured in the first direction, and the second portion is in contact with the interlayer insulating film that surrounds the first portion.

2. The semiconductor device according to claim 1,
wherein a width of the contact member measured in the second direction is smaller than a width of each of the active areas measured in the second direction, and
a width of the second portion measured in the second direction is larger than a width of the first portion measured in the second direction.

3. The semiconductor device according to claim 2, wherein when a section of the second portion is viewed from the first direction, a connection portion between the second portion and a diffusion layer in the active area has a substantially arc shape.

4. The semiconductor device according to claim 3, wherein the substantially arc shape is convex towards the semiconductor substrate.

5. The semiconductor device according to claim 2, wherein when a section of the second portion is viewed from the second direction, a connection portion between the second portion and a diffusion layer in the active area has a substantially arc shape.

6. The semiconductor device according to claim 3, wherein a top surface of the second portion has a shape of a sloping surface inclined upwards with respect to a top surface of the diffusion layer.

7. The semiconductor device according to claim 4, wherein a top surface of the second portion has a shape of a sloping surface inclined upwards with respect to a top surface of the diffusion layer.

8. The semiconductor device according to claim 5, wherein a top surface of the second portion has a shape of a sloping surface inclined upwards with respect to a top surface of the diffusion layer.

9. The semiconductor device according to claim 1, wherein a portion, on a side in the second direction, of the first portion is in contact with a top surface of the element-isolating insulating film.

10. The semiconductor device according to claim 9, wherein a sidewall of the second portion is in contact with a sidewall of the element-isolating insulating film having a top surface being in contact with a bottom surface of the first portion.

11. The semiconductor device according to claim 9, wherein when a section of the second portion is viewed from the first direction, a connection portion between the second portion and a diffusion layer in the active area has a substantially arc shape.

12. The semiconductor device according to claim 10, wherein when a section of the second portion is viewed from the first direction, a connection portion between the second portion and a diffusion layer in the active area has a substantially arc shape.

13. The semiconductor device according to claim 1,
wherein a width of the contact member measured in the second direction is larger than a width of each of the active area measured in the second direction, and
a protruding portion is formed in a central portion, in the second direction, of the active area, and
the contact member is provided on the active area including the protruding portion.

14. The semiconductor device according to claim 13, wherein the protruding portion extends in the second direction.

15. The semiconductor device according to claim 1, wherein the contact member is a polysilicon plug.

16. The semiconductor device according to claim 1, wherein, when viewed in a direction from a top to a bottom surface of the first portion, a planar area of the first portion is smaller than a planar area of the second portion.

17. The semiconductor device according to claim 1, comprising:
in the first direction, a width of the second portion is greater than a width of the first portion; and
in the second direction, a width of the second portion is greater than a width of the first portion.

18. The semiconductor device according to claim 1, comprising:
in the first direction, a width of the second portion is greater than a width of the first portion; and
in the second direction, a width of the second portion is the same as a width of the first portion.

19. The semiconductor device according to claim 1, comprising:
the substrate having a protruding portion extending upwardly from a bottom surface of the second portion into an interior of the second portion.
